(19) United States
(12) Patent Application Publication
(10) Pub. No.: US 2023/0050843 A1
(43) Pub. Date: Feb. 16, 2023

(54) RESISTIVE RANDOM ACCESS MEMORY AND MANUFACTURING METHOD

(71) Applicants: HANGZHOU WEIMING XINKE TECHNOLOGY CO., LTD, Hangzhou, Zhejiang (CN); ADVANDED INSTITUTE OF INFORMATION TECHNOLOGY (AIIT) , PEKING UNIVERSITY, Hangzhou, Zhejiang (CN)

(72) Inventors: Han XIAO, Hangzhou, Zhejiang (CN); Zongwei WANG, Hangzhou, Zhejiang (CN); Ru HUANG, Hangzhou, Zhejiang (CN)

(21) Appl. No.: 17/789,690

(22) PCT Filed: Dec. 15, 2020
(86) PCT No.: PCT/CN2020/136467

§ 371 Date: Jun. 28, 2022

(30) Foreign Application Priority Data
Dec. 30, 2019 (CN) 201911397907.5

(51) Int. Cl. H01L 45/00; H01L 27/24

(52) U.S. Cl. CPC H01L 45/1683; H01L 45/1641; H01L 45/1253; H01L 27/2436; H01L 45/1608

(57) ABSTRACT

Disclosed in Disclosed are a resistive random access memory and a manufacturing method. A memory area of the resistive random access memory comprises a first metal interconnection line, a resistive random access memory unit and a second metal interconnection line that are connected in sequence, wherein the whole or part of a bottom electrode of the resistive random access memory unit is arranged in a short through hole of a barrier layer on the first metal interconnection line; the first metal interconnection line is connected to the bottom electrode of the resistive random access memory unit; and the second metal interconnection line is connected to a top electrode of the resistive random access memory unit. By means of arranging the whole or part of the bottom electrode of the resistive random access memory unit in the short through hole of the barrier layer on the first metal interconnection line, the bottom electrode can be made to be very thin, such that the height of the resistive random access memory unit in a CMOS back end of line is reduced, the thickness, which needs to be occupied, of each layer in the CMOS back end of line is smaller, integration is facilitated, the back end of line of a logic circuit area cannot be influenced, and the total stacking thickness can meet the electrical property requirement of the resistive random access memory. The process integration scheme in the embodiments of the present application can make the integration of an RRAM and a standard CMOS simpler.

### TECHNICAL FIELD

The present application relates to the technical field of resistive random-access memory, and in particular to a resistive random-access memory and a manufacturing method.

### BACKGROUND

A resistive random-access memory (RRAM) is a memory device similar to a sandwich structure. A resistance-variable layer is connected to upper and lower electrode plates at a top and a bottom thereof respectively. By introducing different external voltages to the upper and lower electrodes, physical properties of the resistance-variable layer will change under the action of electric field to show two states, a high resistance state and a low resistance state, thus achieving the function of storing data.

In recent years, as a new type of memory, the resistive random-access memory has been widely studied by people due to its high speed, low power consumption and simple structure. How to embed RRAM in a chip in a way of being compatible with foundry (a manufacturer specializing in producing and manufacturing chips) has become the focus of people's research.

An integrated circuit is fabricated layer by layer using the so-called planar process, including front end of line (FEOL) and back end of line (BEOL).

The front end of line includes: firstly, forming an area (active area) by division on a Si substrate to prepare a transistor, followed by ion implantation to realize N-type and P-type regions; secondly, preparing the gate, followed by ion implantation to complete source and drain of each transistor. This part of the process flow is to realize N-type and P-type field effect transistors on the Si substrate.

The back end of line includes: establishing several layers of conductive metal wires (metal interconnection wires), in which the metal wires of different layers are connected by columnar metal. Each metal wire is a metal layer.

Generally, the RRAM is embedded in BEOL metal layers, but with the reduction of process nodes, a wire width continues to decrease, and the resulting inter-metal dielectric thickness also continues to decrease. However, in order to meet electrical performance requirements of the RRAM, a certain total stack thickness needs to be ensured. Therefore, it becomes all the more challenging to embed the RRAM layer into the BEOL.

Therefore, there is a need to provide a resistive random-access memory with a thinner thickness occupied while also having a total stack thickness that can meet the electrical performance requirements of the resistive random-access memory in the back end of line of CMOS, and a manufacturing method thereof.

### SUMMARY

In order to solve the above problem, the present application proposes a resistive random-access memory and a manufacturing method.

In a first aspect, the present application provides a resistive random-access memory, a memory region of which includes a first metal interconnection wire, a resistive random-access memory cell, and a second metal interconnection wire that are connected in sequence;

an entirety or a part of a bottom electrode of the resistive random-access memory cell is in a short via hole of a barrier layer on the first metal interconnection wire;

the first metal interconnection wire is connected to the bottom electrode of the resistive random-access memory cell; and

the second metal interconnection wire is connected to a top electrode of the resistive random-access memory cell.

Preferably, the resistive random-access memory cell further includes a resistance-variable layer for spacing the bottom electrode and the top electrode apart.

Preferably, a hard mask layer is further included on the top electrode.

Preferably, the resistive random-access memory further includes a logic region;

the logic region includes a third metal interconnection wire in a same dielectric layer as the first metal interconnection wire, and a fourth metal interconnection wire in a same dielectric layer as the second metal interconnection wire; and

the third metal interconnection wire is connected to the fourth metal interconnection wire through a via hole.

In a second aspect, the present application provides a method for manufacturing a resistive random-access memory, which includes:

wiring a CMOS logic circuit fabricated on a substrate;

after wiring to a metal layer where set metal interconnection wires are located, using a photomask to perform short via hole exposure patterning on a memory region to manufacture a resistive random-access memory cell;

filling an interlayer dielectric after completing the exposure patterning of the resistive random-access memory cell; and

performing a standard back-end dual Damascus copper process in the memory region and a logic region, and drawing out the metal interconnection wires.

Preferably, the “using a photomask to perform short via hole exposure patterning on a memory region to manufacture a resistive random-access memory cell” includes:

using the photomask to perform short via hole exposure patterning on a barrier layer of the memory region;

filling a bottom electrode material after degumming;

depositing a resistance-variable layer material and a top electrode material after completion of filling the bottom electrode material; and

using the photomask to perform exposure patterning of resistive random-access memory cell in the memory region to obtain the resistive random-access memory cell.

Preferably, the “filling a bottom electrode material after degumming” includes:

filling the bottom electrode material after degumming; or

filling a metal after degumming, and performing planarization treatment on the filled metal by chemical mechanical grinding, which stops at the barrier layer, followed by bottom electrode material filling; or

filling the bottom electrode material after degumming, and performing planarization treatment on the filled bottom electrode material by chemical mechanical grinding.

Preferably, the “performing planarization treatment on the filled bottom electrode material by chemical mechanical grinding” includes:

performing planarization treatment on the filled bottom electrode material by chemical mechanical grinding, which stops at the barrier layer; or performing planarization treatment on the filled bottom electrode material by chemical mechanical grinding, which stops above the barrier layer.

Preferably, before the “using the photomask to perform exposure patterning of resistive random-access memory cell in the memory region”, the method further includes:

adding a hard mask layer on the top electrode.

Preferably, before the “performing a standard back-end dual Damascus copper process in the memory region and a logic region”, the method further includes:

performing planarization treatment on the filled interlayer dielectric by chemical mechanical grinding.

The present application has the following advantages: by placing the entirety or a part of the bottom electrode of the resistive random-access memory cell in the short via hole of the barrier layer on the first metal interconnection wire, a height of the resistive random-access memory cell in the CMOS back-end process is reduced, so that the thicknesses of various layers that need to be occupied in the CMOS back-end process become smaller, and the total stack thickness can meet the electrical performance requirements of the resistive random-access memory.

### BRIEF DESCRIPTION OF THE DRAWINGS

Upon reading the detailed description of the preferred embodiments below, various other advantages and benefits will become clear to those skilled in the art. The accompanying drawings are only used for the purpose of illustrating preferred embodiments, and should not be considered as a limitation to the present application. Moreover, throughout the drawings, the same reference signs are used to denote the same components, in which:

FIG. 1 is a schematic diagram of a resistive random-access memory provided by the present application;

FIG. 2 is a schematic structural diagram of the resistive random-access memory provided by the present application;

FIG. 3 is a schematic structural diagram of a circuit board of the resistive random-access memory provided by the present application;

FIG. 4 is a schematic diagram showing steps of a method for manufacturing the resistive random-access memory provided by the present application;

FIG. 5 is a schematic diagram of wiring to a metal layer in a back-end process of the method for manufacturing the resistive random-access memory provided by the present application;

FIG. 6 is a schematic diagram of short via hole exposure patterning in the back-end process of the method for manufacturing the resistive random-access memory provided by the present application;

FIG. 7 is a schematic diagram of bottom electrode deposition in the back-end process of the method for manufacturing the resistive random-access memory provided by the present application;

FIG. 8 is a schematic diagram of depositing a resistance-variable layer and a top electrode in the back-end process of the method for manufacturing the resistive random-access memory provided by the present application;

FIG. 9 is a schematic diagram of exposure patterning of a memory region in the back-end process of the method for manufacturing the resistive random-access memory provided by the present application;

FIG. 10 is a schematic diagram of filling an interlayer dielectric in the back-end process of the method for manufacturing the resistive random-access memory provided by the present application; and

FIG. 11 is a schematic diagram of a dual Damascene copper process in the back-end process of the method for manufacturing the resistive random-access memory provided by the present application.

### LIST OF REFERENCE SIGNS

| | | | |
|---|---|---|---|
| 1: | first metal interconnection wire; | 2: | second metal interconnection wire; |
| 3: | resistive random-access memory cell; | 31: | bottom electrode; |
| 32: | resistance-variable layer; | 33: | top electrode; |
| 4: | barrier layer; | 5: | short via hole; |
| 6: | third metal interconnection wire; | 7: | fourth metal interconnection wire; |
| 8: | via hole; | 9: | first dielectric layer; |
| 10: | second dielectric layer; | 11: | memory region; |
| 12: | logic region; | 13: | first metal layer; |
| 14: | second metal layer. | | |

### DETAILED DESCRIPTION

Hereinafter, exemplary embodiments of the present disclosure will be described in greater detail with reference to the accompanying drawings. Although the exemplary embodiments of the present disclosure are shown in the drawings, it should be understood that the present disclosure may be implemented in various forms and should not be limited by the embodiments set forth herein. On the contrary, these embodiments are provided to enable a more thorough understanding of the present disclosure and to fully convey the scope of the present disclosure to those skilled in the art.

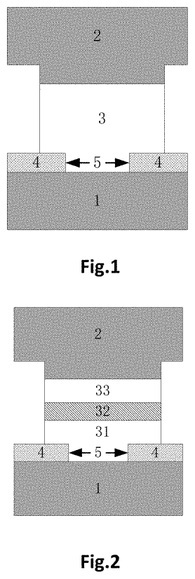

In a first aspect, according to an embodiment of the present application, a resistive random-access memory is provided. As shown in FIGS. 1 and 2, a memory region of the resistive random-access memory includes a first metal interconnection wire, a resistive random-access memory cell, and a second metal interconnection wire that are connected in sequence;

an entirety or a part of a bottom electrode of the resistive random-access memory cell is in a short via hole of a barrier layer on the first metal interconnection wire;

the first metal interconnection wire is connected to the bottom electrode of the resistive random-access memory cell; and

the second metal interconnection wire is connected to a top electrode of the resistive random-access memory cell.

The resistive random-access memory cell further includes a resistance-variable layer for spacing the bottom electrode and the top electrode apart.

A hard mask layer is further included on the top electrode.

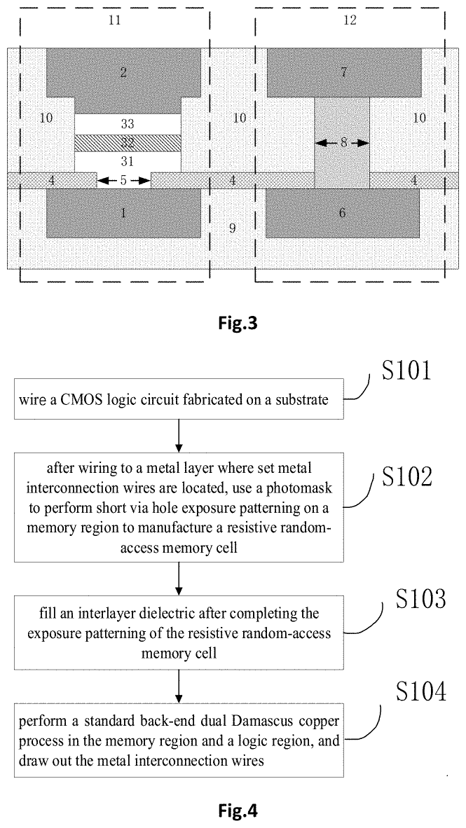

As shown in FIG. 3, the resistive random-access memory further includes a logic region;

the logic region includes a third metal interconnection wire in a same dielectric layer (a first dielectric layer) as the first metal interconnection wire, and a fourth metal interconnection wire in a same dielectric layer (a second dielectric layer) as the second metal interconnection wire; and

the third metal interconnection wire is connected to the fourth metal interconnection wire through a via hole.

The short via hole in the barrier layer for metal interconnection is integrated with the bottom electrode. The short via hole for metal interconnection only takes advantages of the barrier layer for the metal interconnection wires and will not affect the CMOS circuit part.

The interconnection of the top electrode and the second metal interconnection wire is achieved using a metal via hole that is the same as that in the logic region.

In a second aspect, according to an embodiment of the present application, a method for manufacturing a resistive random-access memory is also provided; as shown in FIG. 4, the method includes:

S101: wiring a CMOS logic circuit fabricated on a substrate;

S102: after wiring to a metal layer where set metal interconnection wires are located, using a photomask to perform short via hole exposure patterning on a memory region to manufacture a resistive random-access memory cell;

S103: filling an interlayer dielectric after completing the exposure patterning of the resistive random-access memory cell; and

S104: performing a standard back-end dual Damascus copper process in the memory region and a logic region, and drawing out the metal interconnection wires.

The “using a photomask to perform short via hole exposure patterning on a memory region to manufacture a resistive random-access memory cell” includes:

using the photomask to perform short via hole exposure patterning on a barrier layer of the memory region;

filling a bottom electrode material after degumming;

depositing a resistance-variable layer material and a top electrode material after completion of filling the bottom electrode material; and

using the photomask to perform exposure patterning of resistive random-access memory cell in the memory region to obtain the resistive random-access memory cell.

The “filling a bottom electrode material after degumming” includes:

filling the bottom electrode material after degumming; or

filling a metal after degumming, and performing planarization treatment on the filled metal by chemical mechanical grinding, which stops at the barrier layer, followed by bottom electrode material filling; or

filling the bottom electrode material after degumming, and performing planarization treatment on the filled bottom electrode material by chemical mechanical grinding.

The “performing planarization treatment on the filled bottom electrode material by chemical mechanical grinding” includes:

performing planarization treatment on the filled bottom electrode material by chemical mechanical grinding, which stops at the barrier layer; or performing planarization treatment on the filled bottom electrode material by chemical mechanical grinding, which stops above the barrier layer.

Before the “using the photomask to perform exposure patterning of resistive random-access memory cell in the memory region”, the method further includes:

adding a hard mask layer on the top electrode.

Before the “performing a standard back-end dual Damascus copper process in the memory region and a logic region”, the method further includes:

performing planarization treatment on the filled interlayer dielectric by chemical mechanical grinding.

The “performing a standard back-end dual Damascus copper process in the memory region and a logic region” includes performing exposure patterning in the memory region and the logic region.

Hereinafter, the embodiment of the present application will be further described.

As shown in FIG. 5, first, a CMOS logic circuit is fabricated on a substrate, and then wiring is performed. After wiring to a metal layer (a first metal layer) where the first metal interconnection wire is located, as shown in FIG. 6, a photomask is used to perform short via hole exposure patterning on the barrier layer of the memory region (the exposure patterning step includes degumming); that is, when the normal back-end metal wiring process is completed, after depositing the barrier layer, patterning of short via hole is performed directly on this basis.

The barrier layer may be a copper barrier layer.

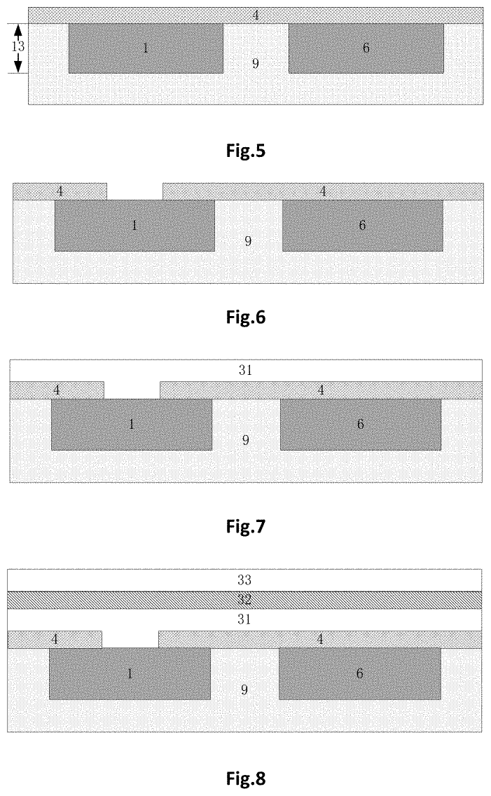

As shown in FIG. 7, after degumming, a bottom electrode material is filled at the short via hole.

Preferably, after degumming, the bottom electrode material can be filled to a thickness of 20-50 nm; or a metal such as copper or tungsten can be filled after degumming, and then the filled metal can be subjected to planarization treatment by chemical mechanical grinding, which stops at the barrier layer, followed by bottom electrode material filling; or the bottom electrode material is filled after degumming, and then the filled bottom electrode material is subjected to planarization treatment by chemical mechanical grinding.

After the short via hole on the first metal interconnection wire is etched and patterned, the short via hole is filled with the bottom electrode material which includes: tantalum nitride (TaN), tantalum (Ta), titanium nitride (TiN), titanium (Ti), copper (Cu), tungsten (W), etc. This material acts as the bottom electrode and can be connected to the metal interconnection wire.

After the bottom electrode material is filled, whether to perform planarization treatment by chemical mechanical grinding can be determined according to specific needs. If planarization treatment is selected, then after the planarization treatment, an upper surface of the bottom electrode can stop at an upper surface of the barrier layer so as to be flush with the upper surface of the barrier layer, or the upper surface of the bottom electrode can be higher than the barrier layer by a certain thickness, preferably by 5-30 nm.

Preferably, the final thickness of the bottom electrode is ≥30 nm and ≤60 nm.

As shown in FIG. 8, after the bottom electrode is completed, a resistance-variable layer material and a top electrode material are deposited in sequence.

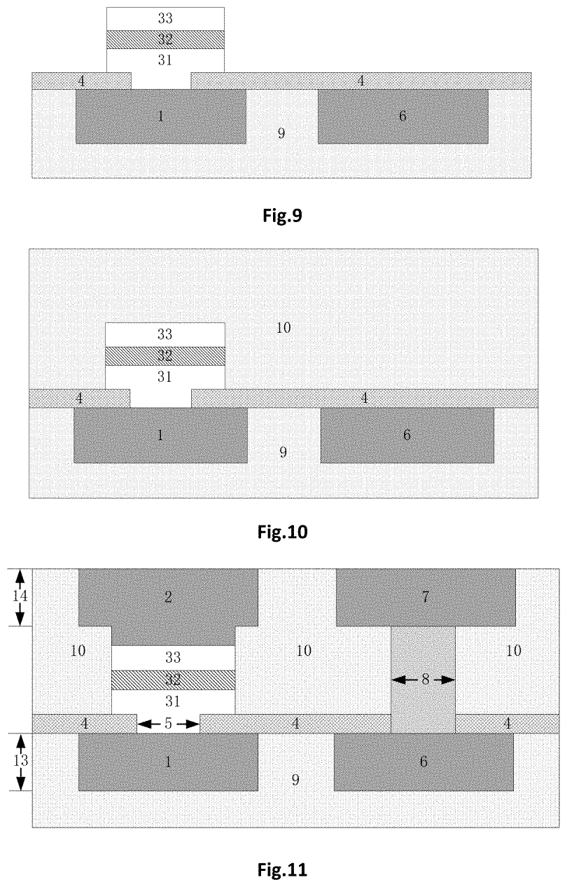

As shown in FIG. 9, the photomask is used to perform exposure patterning of resistive random-access memory cell on the memory region to obtain the resistive random-access memory cell.

Preferably, a thickness of the resistance-variable layer is ≥5 nm and ≤15 nm, and a thickness of the top electrode is ≥20 nm and ≤40 nm.

According to specific needs, a hard mask layer may be added on the top electrode, and the patterning of the resistance-variable layer, the top electrode and the hard mask layer can be completed in one step.

Preferably, the material of the hard mask layer may be silicon nitride, silicon oxide, etc., and its thickness is ≥10 nm and ≤50 nm. As shown in FIG. 10, after the exposure patterning of the resistive random-access memory cell is completed, an interlayer dielectric is filled. After the filling is completed, a planarization treatment is performed on the filled interlayer dielectric.

As shown in FIG. 11 a standard back-end dual Damascus copper process is performed in the memory region and the logic region, and metal interconnection wires are drawn out.

The interconnection of the resistive random-access memory cell and the second metal interconnection wire in the second metal layer is performed using a via hole that is the same as that in the logic region.

In the system of the present application, by placing the entirety or a part of the bottom electrode of the resistive random-access memory cell in the short via hole of the barrier layer on the first metal interconnection wire, the bottom electrode can be made thinner, a height of the resistive random-access memory cell in the CMOS back-end process is reduced, and integration is facilitated, so that the thicknesses of various layers that need to be occupied in the CMOS back-end process become smaller, the back-end process of the logic circuit region will not be affected, and the total stack thickness can meet the electrical performance requirements of the resistive random-access memory. Through the process integration solution in the embodiments of the present application, the integration of RRAM and standard CMOS can be made simpler.

Described above are only specific preferred embodiments of the present application, but the scope of protection of the present application is not limited to this. Changes or substitutions that can be easily devised by those skilled in the art within the technical scope disclosed by the present application should be covered within the scope of protection of the present application. Therefore, the scope of protection of the present application shall be accorded with the scope of protection of the claims.

1. A resistive random-access memory, wherein a memory region of the resistive random-access memory comprises a first metal interconnection wire, a resistive random-access memory cell, and a second metal interconnection wire that are connected in sequence;
an entirety or a part of a bottom electrode of the resistive random-access memory cell is in a short via hole of a barrier layer on the first metal interconnection wire;
the first metal interconnection wire is connected to the bottom electrode of the resistive random-access memory cell; and
the second metal interconnection wire is connected to a top electrode of the resistive random-access memory cell.

2. The resistive random-access memory according to claim 1, wherein the resistive random-access memory cell further comprises a resistance-variable layer for spacing the bottom electrode and the top electrode apart.

3. The resistive random-access memory according to claim 1, wherein a hard mask layer is further included on the top electrode.

4. The resistive random-access memory according to claim 1, further comprising a logic region;
wherein the logic region comprises a third metal interconnection wire in a same dielectric layer as the first metal interconnection wire, and a fourth metal interconnection wire in a same dielectric layer as the second metal interconnection wire; and
the third metal interconnection wire is connected to the fourth metal interconnection wire through a via hole.

5. A method for manufacturing a resistive random-access memory, comprising:
wiring a CMOS logic circuit fabricated on a substrate;
after wiring to a metal layer where set metal interconnection wires are located, using a photomask to perform short via hole exposure patterning on a memory region to manufacture a resistive random-access memory cell;
filling an interlayer dielectric after completing the exposure patterning of the resistive random-access memory cell; and
performing a standard back-end dual Damascus copper process in the memory region and a logic region, and drawing out the metal interconnection wires.

6. The method for manufacturing a resistive random-access memory according to claim 5, wherein the “using a photomask to perform short via hole exposure patterning on a memory region to manufacture a resistive random-access memory cell” comprises:
using the photomask to perform short via hole exposure patterning on a barrier layer of the memory region;
filling a bottom electrode material after degumming;
depositing a resistance-variable layer material and a top electrode material after completion of filling the bottom electrode material; and
using the photomask to perform exposure patterning of resistive random-access memory cell in the memory region to obtain the resistive random-access memory cell.

7. The method for manufacturing a resistive random-access memory according to claim 6, wherein the “filling a bottom electrode material after degumming” comprises:
filling the bottom electrode material after degumming; or
filling a metal after degumming, and performing planarization treatment on the filled metal by chemical mechanical grinding, which stops at the barrier layer, followed by bottom electrode material filling; or
filling the bottom electrode material after degumming, and performing planarization treatment on the filled bottom electrode material by chemical mechanical grinding.

8. The method for manufacturing a resistive random-access memory according to claim 7, wherein the “performing planarization treatment on the filled bottom electrode material by chemical mechanical grinding” comprises:
performing planarization treatment on the filled bottom electrode material by chemical mechanical grinding, which stops at the barrier layer; or performing planarization treatment on the filled bottom electrode material by chemical mechanical grinding, which stops above the barrier layer.

9. The method for manufacturing a resistive random-access memory according to claim 6, wherein before the “using the photomask to perform exposure patterning of resistive random-access memory cell in the memory region”, the method further comprises:
adding a hard mask layer on the top electrode.

10. The method for manufacturing a resistive random-access memory according to claim 5, wherein before the “performing a standard back-end dual Damascus copper process in the memory region and a logic region”, the method further comprises:
performing planarization treatment on the filled interlayer dielectric by chemical mechanical grinding.
